(19) United States
(12) Patent Application Publication
(10) Pub. No.: US 2026/0173791 A1
(43) Pub. Date: Jun. 18, 2026

(54) SUBSTRATE PROCESSING SYSTEM, SUBSTRATE PROCESSING METHOD USING THE SAME, AND SEMICONDUCTOR DEVICE MANUFACTURING METHOD INCLUDING THE SAME

(71) Applicant: SAMSUNG ELECTRONICS CO., LTD., Suwon-si (KR)

(72) Inventors: Jinoh IM, Suwon-si (KR); Donghoon KWON, Suwon-si (KR); ILYOUNG YOON, Suwon-si (KR)

(73) Assignee: SAMSUNG ELECTRONICS CO., LTD., Suwon-si (KR)

(21) Appl. No.: 19/276,806

(22) Filed: Jul. 22, 2025

(30) Foreign Application Priority Data
Dec. 17, 2024 (KR) 10-2024-0188661

(51) Int. Cl. H01L 21/67; H01L 21/3065; H10D 30/01

(52) U.S. Cl. CPC H10P 72/0421; H10P 50/242; H10D 30/019

(57) ABSTRACT

A substrate processing system includes a measuring apparatus configured to measure a surface level of a substrate, a transfer module connected to the measuring apparatus, a first polishing apparatus connected to the transfer module and including a first chuck and a first plasma nozzle facing the first chuck, and a second polishing apparatus connected to the transfer module and including a second chuck and a second plasma nozzle facing the second chuck, where a diameter of the second plasma nozzle is larger than a diameter of the first plasma nozzle.

### CROSS-REFERENCE TO RELATED APPLICATION

This application is based on and claims priority under 35 U.S.C. § 119 of Korean Patent Application No. 10-2024-0188661, filed on Dec. 17, 2024, in the Korean Intellectual Property Office, the disclosure of which is incorporated by reference herein in its entirety.

### BACKGROUND

The present disclosure herein relates to a substrate processing system, a substrate processing method using the same, and a semiconductor device manufacturing method including the same.

Manufacturing a semiconductor device may be performed through various processes. For example, manufacturing a semiconductor device may be performed through a photo process, an etching process, a deposition process, and the like on a substrate. Planarizing a surface of the substrate may be required before each process. To this end, a polishing process may be performed on the substrate. The polishing process may be performed in various methods. For example, a process using plasma may be used for planarizing the substrate.

Information included in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a substrate processing system that may be capable of efficiently polishing a substrate, a substrate processing method using the same, and a semiconductor device manufacturing method including the same.

Additional aspects will be set forth in part in the description which follows and, in part, will be apparent from the description, or may be learned by practice of the presented embodiments.

According to an aspect of an example embodiment, a substrate processing system may include a measuring apparatus configured to measure a surface level of a substrate, a transfer module connected to the measuring apparatus, a first polishing apparatus connected to the transfer module and including a first chuck and a first plasma nozzle facing the first chuck, and a second polishing apparatus connected to the transfer module and including a second chuck and a second plasma nozzle facing the second chuck, where a diameter of the second plasma nozzle is larger than a diameter of the first plasma nozzle.

According to an aspect of an example embodiment, a substrate processing method may include measuring a surface level of a substrate, performing a polishing process on the substrate based on the measured surface level of the substrate, where performing of the polishing process includes performing a first polishing process in a first polishing apparatus, and performing a second polishing process in a second polishing apparatus, and a temperature of the first polishing process is lower than a temperature of the second polishing process.

According to an aspect of an example embodiment, a semiconductor device manufacturing method may include forming an active pattern, a source/drain pattern, a channel pattern, and a gate electrode on a first surface of a substrate, forming a metal layer comprising lines on the gate electrode, performing a polishing process on a second surface of the substrate that is opposite to the first surface, and forming a power delivery network layer on the second surface, where the polishing process includes a first polishing process performed at a first temperature, and a second polishing process performed at a second temperature that is different from the first temperature.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a diagram illustrating a substrate processing system according to one or more embodiments;

FIGS. 2A and 2B are diagrams illustrating polishing apparatuses according to one or more embodiments;

FIG. 3 is a diagram illustrating region X of FIG. 2A according to one or more embodiments;

FIG. 4 is a diagram illustrating region Y of FIG. 2B according to one or more embodiments;

FIG. 5A is a diagram illustrating a substrate processing system according to one or more embodiments;

FIG. 5B is a diagram illustrating a plasma nozzle of a third polishing apparatus according to one or more embodiments;

FIG. 6 is a flowchart illustrating a substrate processing method according to one or more embodiments;

FIGS. 7 to 9 are diagrams illustrating a substrate processing method according to one or more embodiments; and

FIGS. 10 to 16B are diagrams illustrating a semiconductor device manufacturing method according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

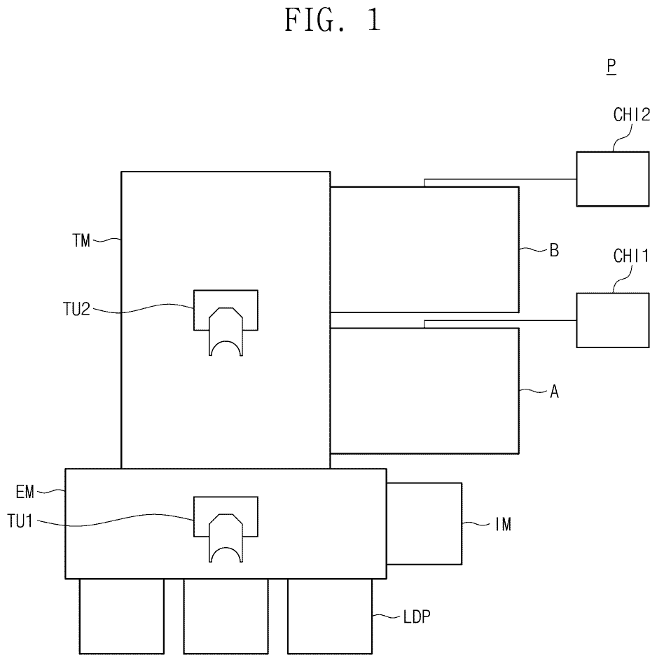

FIG. 1 is a diagram illustrating a substrate processing system according to one or more embodiments.

Referring to FIG. 1, a substrate processing system P may be provided. The substrate processing system P according to one or more embodiments may be one system configured with a plurality of apparatuses capable of performing a semiconductor process on a surface of a substrate. The substrate processing system P may also be referred to as a substrate processing apparatus that is an assembly of apparatuses capable of performing a semiconductor process on a surface of a substrate. The term “substrate” may include a semiconductor device integrated in a silicon (Si) wafer but is not limited thereto. The substrate processing system P may include a load port LDP, an interface module EM, a measuring apparatus IM, a transfer module TM, a first polishing apparatus A, a second polishing apparatus B, a first chiller CHI1, a second chiller CHI2, and the like.

The load port LDP may locate a front opening unified pod (FOUP) which stores a substrate. The substrate in the FOUP may be in a state in which various manufacturing processes for a semiconductor device are performed on the substrate. The load port LDP may fix and dock the FOUP so that the FOUP contacts the interface module EM. The load port LDP may be provided in plurality, but embodiments are not limited thereto.

The interface module EM may be located between the load port LDP and the transfer module TM. The interface module EM may connect the load port LDP and the transfer module TM. The interface module EM may include a first transfer unit TU1 therein. The first transfer unit TU1 may transfer the substrate. For example, the first transfer unit TU1 may transfer the substrate to the measuring apparatus IM and the transfer module TM.

The measuring apparatus IM may be located on one side of the interface module EM. The measuring apparatus IM may measure a surface level of the substrate. For example, the measuring apparatus IM may measure a surface level on a plurality of regions of the substrate which are two-dimensionally arranged. Accordingly, a surface level of the overall substrate may be measured. A polishing process may be performed on the substrate in the first polishing apparatus A and the second polishing apparatus B based on a measured surface level of the substrate.

A level may refer to a height (or distance) from an upper surface or a lower surface of a substrate in a direction perpendicular to an upper surface or a lower surface of the substrate. For example, a surface level of the substrate may refer to a height, roughness, curvature, and the like of a surface of the substrate.

The transfer module TM may be connected to the interface module EM. The transfer module TM may include a second transfer unit TU2 therein. The second transfer unit TU2 of the transfer module TM may transfer the substrate to the first polishing apparatus A and the second polishing apparatus B. The transfer module TM may be connected to a pump, and an inside thereof may be in a vacuum state, but embodiments are not limited thereto. According to one or more embodiments, a load-lock chamber may be further provided between the transfer module TM and the interface module EM.

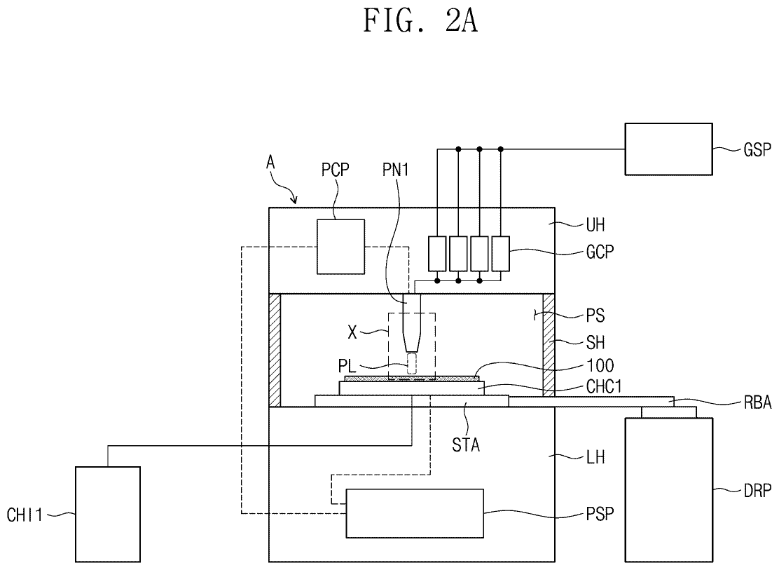

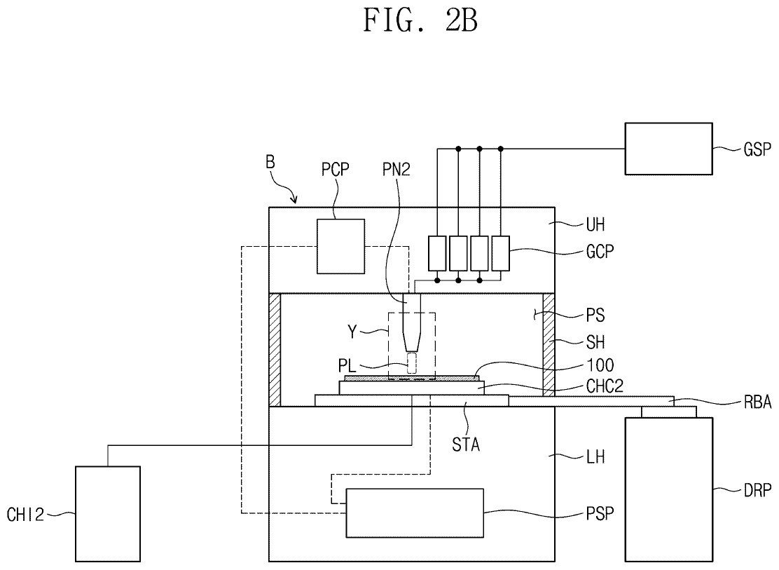

Each of the first polishing apparatus A and the second polishing apparatus B may be located on one side of the transfer module TM and connected to the transfer module TM. The first polishing apparatus A and the second polishing apparatus B may be spaced apart from each other and may not be directly connected to each other. Each of the first polishing apparatus A and the second polishing apparatus B may polish the substrate. More specifically, each of the first polishing apparatus A and the second polishing apparatus B may partially polish the substrate by using plasma. The first polishing apparatus A and the second polishing apparatus B will be described later in detail with reference to FIGS. 2A to 4.

The first chiller CHI1 and the second chiller CHI2 may be connected to the first polishing apparatus A and the second polishing apparatus B. For example, the first chiller CHI1 may be connected to the first polishing apparatus A, and the second chiller CHI2 may be connected to the second polishing apparatus B. The first chiller CHI1 and the second chiller CHI2 may be configured to control temperatures of the first polishing apparatus A and the second polishing apparatus B, respectively, by using a coolant.

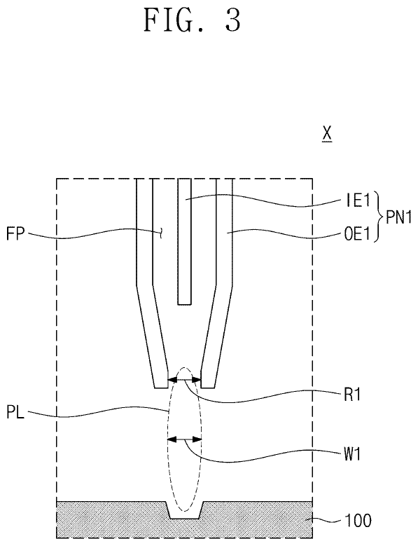

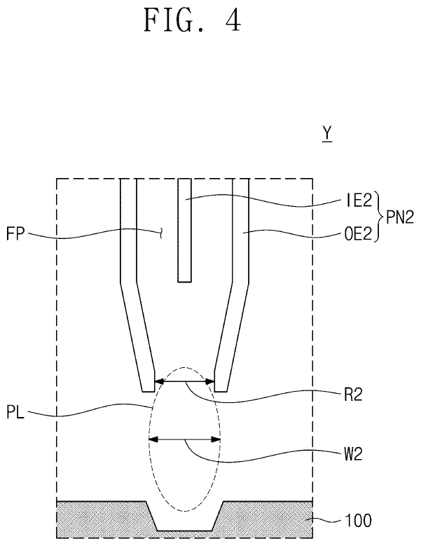

FIGS. 2A and 2B are diagrams illustrating polishing apparatuses according to one or more embodiments. FIG. 3 is a diagram illustrating region X of FIG. 2A according to one or more embodiments. FIG. 4 is a diagram illustrating region Y of FIG. 2B according to one or more embodiments.

Referring to FIGS. 2A and 2B, the first polishing apparatus A and the second polishing apparatus B may be provided. The first polishing apparatus A and the second polishing apparatus B may perform a polishing process on a substrate 100. For example, the polishing process may be a process of partially removing a surface of the substrate 100 by using plasma PL formed on the substrate 100. Each of the first polishing apparatus A and the second polishing apparatus B may include a lower housing LH, an upper housing UH on the lower housing LH, and a side housing SH between the lower housing LH and the upper housing UH.

A power supply portion PSP may be provided in the lower housing LH of each of the first polishing apparatus A and the second polishing apparatus B. The power supply portion PSP may be connected to a power control portion PCP to be described later in the upper housing UH. In addition, the power supply portions PSP may be connected to a first chuck CHC1 and a second chuck CHC2 to be described later. For example, the power supply portions PSP may supply RF power to the power control portions PCP, and supply DC power to the first chuck CHC1 and the second chuck CHC2, but embodiments are not limited thereto. According to one or more embodiments, the power supply portion PSP may include a plurality of power supply portions having different frequencies.

A power control portion PCP may be provided in the upper housing UH of each of the first polishing apparatus A and the second polishing apparatus B. The power control portions PCP may be connected to the power supply portions PSP and a first plasma nozzle PN1 and a second plasma nozzle PN2 to be described later. For example, the power supply portions PSP and the first plasma nozzle PN1 and the second plasma nozzle PN2 may be connected through the power control portions PCP. The power control portions PCP may supply the RF power to the first plasma nozzle PN1 and the second plasma nozzle PN2 by efficiently matching the RF power supplied from the power supply portions PSP. According to one or more embodiments, the power control portion PCP may be an RF matcher.

A gas control portion GCP may be provided in the upper housing UH of each of the first polishing apparatus A and the second polishing apparatus B. The gas control portion GCP may be connected to a gas supply portion GSP. The gas supply portion GSP may supply various fluids required for a polishing process. The gas control portion GCP may be supplied with a fluid from the gas supply portion GSP. The gas control portions GCP may be connected to the first plasma nozzle PN1 and the second plasma nozzle PN2 to be described later. For example, the gas supply portions GSP and the first plasma nozzle PN1 and the second plasma nozzle PN2 may be connected through the gas control portions GCP. The gas control portions GCP may control flow rate of the fluid supplied from the gas supply portions GSP and supply the fluid to the first plasma nozzle PN1 and the second plasma nozzle PN2. The gas control portion GCP may be a mass flow controller (MFC). According to one or more embodiments, the gas control portion GCP may be provided in plurality, and fluids of different kinds may be simultaneously supplied.

The side housing SH of each of the first polishing apparatus A and the second polishing apparatus B may connect the upper housing UH and the lower housing LH. A process space PS may be provided between the upper housing UH and the lower housing LH due to the side housing SH. For example, the process space PS may be a space in which a polishing process is performed. The process space PS may be in a vacuum pressure state, but embodiments are not limited thereto.

A stage STA may be provided on the lower housing LH of each of the first polishing apparatus A and the second polishing apparatus B. The stage STA may be located in the process space PS. The stage STA may be configured to move in a horizontal direction on the lower housing LH. For example, a driving portion DRP may be connected to a robot arm RBA extending into the process space PS. The robot arm RBA may be coupled to the stage STA. That is, the driving portion DRP may move the stage STA in a horizontal direction by using the robot arm RBA.

The first polishing apparatus A may include the first chuck CHC1 on the stage STA, and the second polishing apparatus B may include the second chuck CHC2 on the stage STA. Each of the first chuck CHC1 and the second chuck CHC2 may be located in the process space PS and may support and fix the substrate 100. For example, the first chuck CHC1 and the second chuck CHC2 may fix the substrate 100 by using the DC power supplied from the power supply portion PSP. The first chuck CHC1 may be connected to the first chiller CHI1, and the second chuck CHC2 may be connected to the second chiller CHI2. That is, the first chiller CHI1 may control a temperature of the first chuck CHC1 of the first polishing apparatus A, and the second chiller CHI2 may control a temperature of the second chuck CHC2 of the second polishing apparatus B.

According to one or more embodiments, a temperature of the first chuck CHC1 may be lower than a temperature of the second chuck CHC2. Accordingly, a temperature of the substrate 100 on the first chuck CHC1 may be lower than a temperature of the substrate 100 on the second chuck CHC2. For example, a temperature of the first chuck CHC1 may have a predefined value in a range of about 80° C. to about 120° C. A temperature of the second chuck CHC2 may have a predefined value in a range of about 250° C. to about 300° C. That is, the substrate processing system P of FIG. 1 may be configured so that a temperature of the first chuck CHC1 is lower than a temperature of the second chuck CHC2.

The first polishing apparatus A may include the first plasma nozzle PN1 facing or above the first chuck CHC1, and the second polishing apparatus B may include the second plasma nozzle PN2 facing or above the second chuck CHC2. Each of the first plasma nozzle PN1 and the second plasma nozzle PN2 may be coupled to the upper housing UH. Each of the first plasma nozzle PN1 and the second plasma nozzle PN2 may be supplied with RF power from the power supply portion PSP. Each of the first plasma nozzle PN1 and the second plasma nozzle PN2 may be supplied with various fluids from the gas supply portion GSP. Each of the first plasma nozzle PN1 and the second plasma nozzle PN2 may form plasma PL on the substrate 100 by using the RF power and the fluids.

Referring to FIG. 3, which is an enlarged view of region X of FIG. 2A, the first plasma nozzle PN1 may include a first inner electrode IE1 and a first outer electrode OE1. The first inner electrode IE1 may be located in the first outer electrode OE1. Since the first inner electrode IE1 and the first outer electrode OE1 are spaced apart from each other, a fluid path FP may be provided in the first plasma nozzle PN1. For example, each of the first inner electrode IE1 and the first outer electrode OE1 may be connected to the power supply portion PSP through the power control portion PCP. The fluid path FP may be connected to the gas supply portion GSP through the gas control portion GCP. Accordingly, fluids may be supplied between the first inner electrode IE1 and the first outer electrode OE1.

More specifically, the first inner electrode IE1 and the first outer electrode OE1 may form an electric field. The electric field formed with the first inner electrode IE1 and the first outer electrode OE1 may ionize the fluids. The plasma PL may be formed due to the ionization of the fluids, and the plasma PL may be discharged, in a jet form, to the outside of the first plasma nozzle PN1.

Referring to FIG. 4, which is an enlarged view of region Y of FIG. 2B, the second plasma nozzle PN2 may include a second inner electrode IE2 and a second outer electrode OE2 spaced apart from each other and provide a fluid path FP therein. The second inner electrode IE2 and the second outer electrode OE2 may be connected to the power supply portion PSP, and the fluid path FP may be connected to the gas supply portion GSP. For example, the second plasma nozzle PN2 may form and discharge the plasma PL in substantially the same method as the first plasma nozzle PN1.

The first plasma nozzle PN1 may have a first diameter R1 at a portion at which the plasma PL is discharged (i.e., toward a lower end of the first plasma nozzle PN1 that faces the corresponding chuck). The plasma PL discharged from the first plasma nozzle PN1 may be formed to a first width W1. The first diameter R1 and the first width W1 may be substantially the same as each other, but embodiments are not limited thereto. In addition, the second plasma nozzle PN2 may have a second diameter R2 at a portion at which the plasma PL is discharged (i.e., toward a lower end of the second plasma nozzle PN2 that faces the corresponding chuck). The plasma PL discharged from the second plasma nozzle PN2 may be formed to a second width W2. The second diameter R2 and the second width W2 may be substantially the same as each other, but embodiments are not limited thereto.

According to one or more embodiments, the first diameter R1 may be smaller than the second diameter R2. For example, the first diameter R1 may be about 8 mm to about 10 mm. The second diameter R2 may be about 20 mm to about 30 mm. That is, the diameter of the output area (i.e., the discharge area) of the first nozzle PN1 may be less than the diameter of the output area (i.e., the discharge area) of the second nozzle PN2. As the diameter of the output area of the first nozzle PN1 may be less than the diameter of the output area of the second nozzle PN2, other dimensions may be similarly correspond. For example, the width of the upper portion of the first nozzle PN1 may be less than the width of the upper portion of the second nozzle PN2. The distance between the outer electrode OE1 and the inner electrode IE1 of the first nozzle PN1 may be less than the distance between the outer electrode OE2 and the inner electrode IE2 of the second nozzle PN2. Accordingly, a size of the plasma PL discharged from the first plasma nozzle PN1 may be smaller than a size of the plasma PL discharged from the second plasma nozzle PN2. That is, the first width W1 of the plasma PL discharged from the first plasma nozzle PN1 may be smaller than the second width W2 of the plasma PL discharged from the second plasma nozzle PN2.

Referring back to FIGS. 2A to 4, the first polishing apparatus A and the second polishing apparatus B may include substantially the same components except for the first and second plasma nozzles PN1 and PN2 and the first and second chucks CHC1 and CHC2. For example, the first polishing apparatus A and the second polishing apparatus B may have different polishing rate from each other with respect to the substrate 100 by using plasma nozzles having different diameters from each other and chucks having different temperatures from each other.

More specifically, polishing rate of the substrate 100 by the plasma PL may be described by Equation (1).

$$R = C \times {j}_{F} \times exp ( - \frac{{E}_{A}}{{k}_{B} \times {T}_{S}} ) \qquad ( 1 )$$

In Equation (1), R corresponds to polishing rate of the substrate 100 by the plasma PL. Also, C corresponds to a constant value according to a fluid, j_{F} corresponds to flow rate of the fluid, E_{A} corresponds to activation energy, k_{B} corresponds to a Boltzmann constant, and T_{S} corresponds to a surface temperature of the substrate 100. Thus, polishing rate may be controlled by flow rate of the fluid and a surface temperature of the substrate 100. For example, as flow rate of the fluid is small and a surface temperature of the substrate 100 is low, polishing rate may decrease. As flow rate of the fluid is large and a surface temperature of the substrate 100 is high, polishing rate may increase.

According to one or more embodiments, the first polishing apparatus A may partially shallowly polish the substrate 100 at a small width by using the first plasma nozzle PN1 having a small diameter and the first chuck CHC1 having a low temperature. That is, the first polishing apparatus A may perform a precise polishing process. On the other hand, the second polishing apparatus B may partially deeply polish the substrate 100 at a large width by using the second plasma nozzle PN2 having a large diameter and the second chuck CHC2 having a high temperature. That is, the second polishing apparatus B may perform a rapid polishing process. Thus, the substrate processing system P of FIG. 1 may efficiently polish the substrate 100 by using polishing process of various kinds.

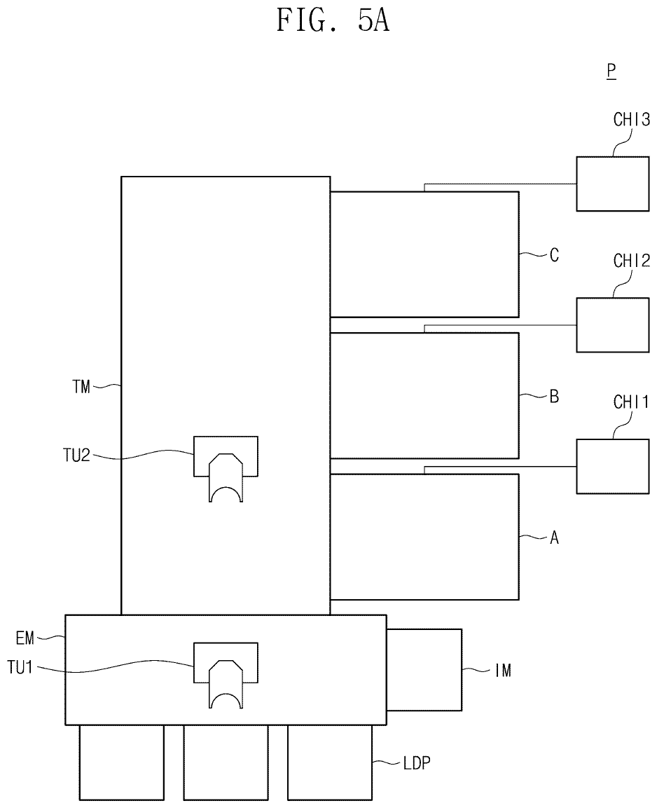

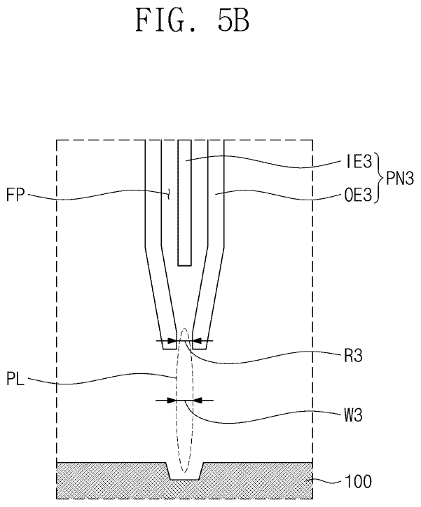

FIG. 5A is a diagram illustrating a substrate processing system according to one or more embodiments. FIG. 5B is a diagram illustrating a plasma nozzle of a third polishing apparatus according to one or more embodiments.

Referring to FIGS. 5A, the substrate processing system P may further include a third polishing apparatus C and a third chiller CHI3 connected to the third polishing apparatus C. Like the first polishing apparatus A and the second polishing apparatus B, the third polishing apparatus C may be connected to the transfer module TM, and spaced apart from the first polishing apparatus A and the second polishing apparatus B.

The third polishing apparatus C may include substantially the same components as the first polishing apparatus A and the second polishing apparatus B. For example, the third polishing apparatus C may include the lower housing LH, which provides the power supply portion PSP, and the upper housing UH which provides the power control portion PCP and the gas control portion GCP, as described with reference to FIG. 2.

Referring to FIG. 5B, in addition, the third polishing apparatus C may include a third chuck on the stage STA and a third plasma nozzle PN3 on the third chuck in the process space PS between the lower housing LH and the upper housing UH. The third chiller CHI3 may be connected to the third chuck and control a temperature of the third chuck.

The third plasma nozzle PN3 may include a third inner electrode IE3 and a third outer electrode OE3 spaced apart from each other and provide a fluid path FP therein. The third inner electrode IE3 and the third outer electrode OE3 may be connected to the power supply portion PSP, and the fluid path FP may be connected to the gas supply portion GSP. For example, the third plasma nozzle PN3 may form and discharge the plasma PL in substantially the same method as the first plasma nozzle PN1 and the second plasma nozzle PN2. In addition, the third plasma nozzle PN3 may have a third diameter R3 at a portion at which the plasma PL is discharged (i.e., toward a lower end of the third plasma nozzle PN3 that faces the corresponding chuck). The plasma PL discharged from the third plasma nozzle PN3 may be formed to a third width W3. The third diameter R3 and the third width W3 may be substantially the same as each other, but embodiments are not limited thereto.

In addition, the diameter R3 of the third plasma nozzle PN3 may be smaller than the first diameter R1 of the first plasma nozzle PN1 and the second diameter R2 of the second plasma nozzle PN2 described with reference to FIGS. 3 and 4. Thus, the third polishing apparatus C may perform a further precise polishing process than the first polishing apparatus A.

According to one or more embodiments, a temperature of the third chuck may be lower than a temperature of the first chuck CHC1 and a temperature of the second chuck CHC2 described with reference to FIG. 2. For example, a temperature of the third chuck may have a predefined value in a range of about 0° C. to about 40° C.

According to one or more embodiments, at least one of the first polishing apparatus A, the second polishing apparatus B, and the third polishing apparatus C may be provided in plurality. That is, the substrate processing system P may include two or more first polishing apparatuses A, second polishing apparatuses B, or third polishing apparatuses C. In this case, the first to third polishing apparatuses A, B, and C may be disposed on both sides of the transfer module TM.

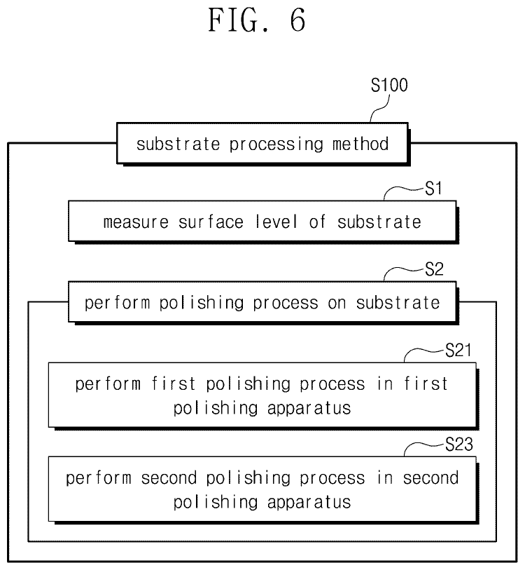

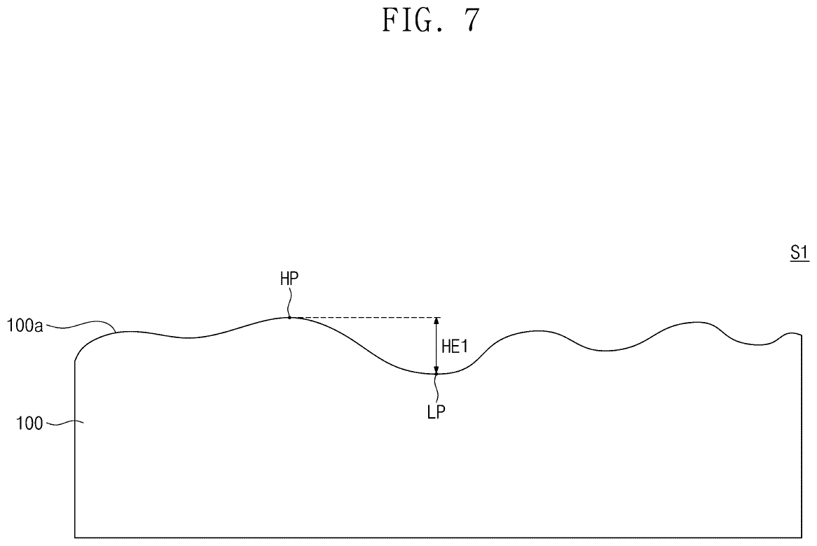

FIG. 6 is a flowchart illustrating a substrate processing method according to one or more embodiments. FIGS. 7 to 9 are diagrams illustrating a substrate processing method according to one or more embodiments.

Referring to FIG. 6, a substrate processing method S100 may be provided. The substrate processing method S100 may be a method of processing a substrate by using the substrate processing system P described with reference to FIGS. 1 to 5B. The substrate processing method S100 may include measuring a surface level of a substrate in operation S1 and performing a polishing process on the substrate in operation S2.

The performing of the polishing process on the substrate of operation S2 may include performing a first polishing process in a first polishing apparatus in operation S21 and performing a second polishing process in a second polishing apparatus in operation S23.

Referring to FIGS. 6 and 7 together with FIG. 1, the measuring of a surface level of the substrate in operation S1 may be performed by the measuring apparatus IM of FIG. 1. The measuring apparatus IM may measure a surface level of a substrate 100 through a sensor using an optical signal. A surface 100a of the substrate 100 may not be flat due to various semiconductor device manufacturing processes. For example, the surface 100a of the substrate 100 may be curved and have a highest point HP and a lowest point LP. A difference between the highest point HP and the lowest point LP may be a first height HE1.

The measuring apparatus IM may transmit information about a measured surface level of the substrate 100 to the first polishing apparatus A and the second polishing apparatus B. Each of the first polishing apparatus A and the second polishing apparatus B may perform a polishing process based on the surface level, of the substrate 100, measured in the measuring apparatus IM. To this end, the measuring of a surface level of the substrate in operation S1 may be performed before the polishing process.

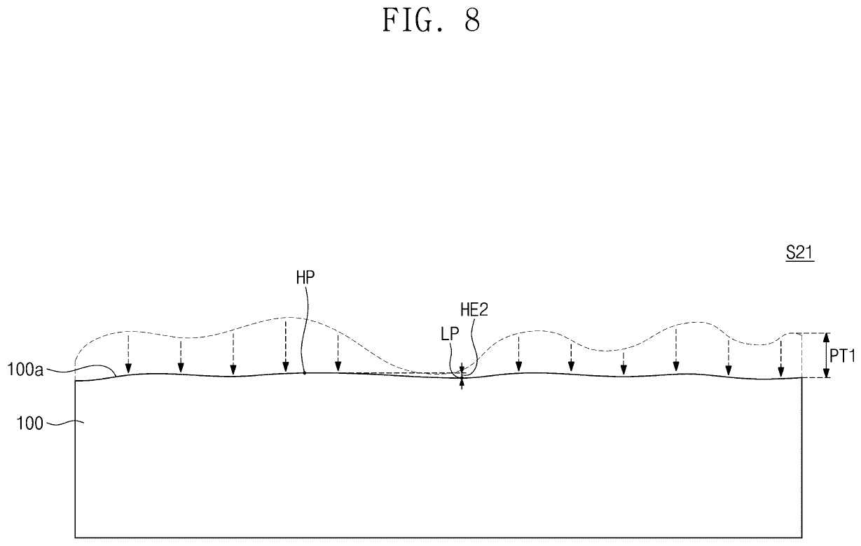

Referring to FIGS. 6 and 8 together with FIG. 2A, the performing of the first polishing process in the first polishing apparatus in operation S21 may include preparing the substrate 100 in the first polishing apparatus A, forming the plasma PL on the substrate 100 by using the first plasma nozzle PN1 of the first polishing apparatus A, and moving the first chuck CHC1 on the stage STA in a horizontal direction.

More specifically, the substrate 100 may be transferred from the measuring apparatus IM of FIG. 1 to the first polishing apparatus A by the first transfer unit TU1 and the second transfer unit TU2. The substrate 100 transferred to the first polishing apparatus A may be disposed on the first chuck CHC1 of the first polishing apparatus A. The first chuck CHC1 may support and fix the substrate 100. That is, the preparing of the substrate 100 in the first polishing apparatus A may include arranging the substrate 100 on the first chuck CHC1 of the first polishing apparatus A.

Thereafter, the plasma PL may be formed on the substrate 100 by supplying RF power and fluids to the first plasma nozzle PN1. The first chuck CHC1 may move in a horizontal direction in a state in which the plasma PL is formed on the surface 100a of the substrate 100. The substrate 100 may move in a horizontal direction together with the first chuck CHC1, and thus the surface 100a of the substrate 100 may be continuously polished by the plasma PL.

For example, the substrate 100 may move slow and may be exposed to the plasma PL for long time for a portion that needs to be greatly polished. The substrate 100 may move fast and may be exposed to the plasma PL for short time for a portion that needs to be slightly polished. That is, the substrate 100 may move slow and have a large amount of polishing for a portion adjacent to the highest point HP, and the substrate 100 may move fast and have a small amount of polishing for a portion adjacent to the lowest point LP. Accordingly, a difference between the highest point HP and the lowest point LP may be reduced from the first height HE1 to a second height HE2. For example, the second height HE2 may be equal to or smaller than about 10 nm.

In other words, the first polishing process according to one or more embodiments may be a polishing process of reducing a difference between the highest point HP and the lowest point LP of the surface 100a of the substrate 100. Accordingly, the surface 100a of the substrate 100 may be substantially flat. Thus, the substrate 100 may have a uniform surface level. A thickness of the substrate 100 may be reduced by a first polishing thickness PT1 due to the first polishing process. For example, the first polishing thickness PT1 may be about 50 nm to about 300 nm.

A surface temperature of the substrate 100 may increase due to the plasma PL in the first polishing process. In this case, the first chiller CHI1 may maintain temperatures of a surface of the substrate 100 on the first chuck CHC1 and the first chuck CHC1 to be constant. Thus, overpolishing due to a change in surface temperature of the substrate 100 may be prevented.

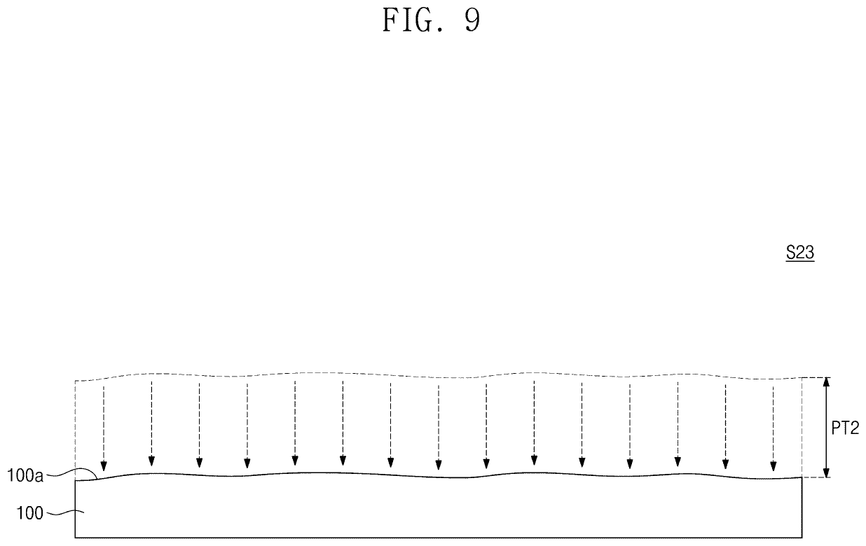

Referring to FIGS. 6 and 9 together with FIG. 2B, the performing of the second polishing process in the second polishing apparatus in operation S23 may include preparing the substrate 100 in the second polishing apparatus B, forming the plasma PL on the substrate 100 by using the second plasma nozzle PN2 of the second polishing apparatus B, and moving the second chuck CHC2 on the stage STA in a horizontal direction.

More specifically, the substrate 100 may be transferred from the first polishing apparatus A of FIG. 1 to the second polishing apparatus B by the second transfer unit TU2. The substrate 100 transferred to the second polishing apparatus B may be disposed on the second chuck CHC2 of the second polishing apparatus B. The second chuck CHC2 may support and fix the substrate 100.

Thereafter, the plasma PL may be formed on the substrate 100 by supplying RF power and fluids to the second plasma nozzle PN2. The second chuck CHC2 may move in a horizontal direction in a state in which the plasma PL is formed on the surface 100a of the substrate 100.

Since the substrate 100 has a uniform surface level due to the first polishing process, the second polishing process may polish the substrate 100 overall with a constant amount of polishing. That is, the substrate 100 may move at constant speed. In other words, the second polishing process according to one or more embodiments may be a polishing process of uniformly reducing a thickness of the substrate 100. Accordingly, the surface 100a of the substrate 100 may be lowered overall. Thus, the substrate 100 having a certain thickness may be provided. A thickness of the substrate 100 may be reduced by a second polishing thickness PT2 due to the second polishing process. For example, the second polishing thickness PT2 may be equal to or greater than about 1000 nm.

A surface temperature of the substrate 100 may also increase due to the plasma PL in the second polishing process as in the first polishing process. In this case, the second chiller CHI2 may maintain temperatures of a surface of the substrate 100 on the second chuck CHC2 and the second chuck CHC2 to be constant.

According to one or more embodiments, the first polishing process may be performed after the second polishing process. A thickness of the substrate 100 may be reduced by uniformly polishing the substrate 100. Thereafter, the substrate 100 may be partially polished so as to have a uniform surface level.

According to one or more embodiments, the measuring of a surface level of the substrate in operation S1 may be performed between the first polishing process and the second polishing process. The measuring apparatus IM of FIG. 1 may measure a difference between the highest point HP and the lowest point LP of the surface 100a of the substrate 100 after the first polishing process. For example, in a case in which the second height HE2 is equal to or greater than about 10 nm, the first polishing process may be performed again.

According to one or more embodiments, the measuring of a surface level of the substrate may be performed after a polishing process. The measuring apparatus IM of FIG. 1 may measure a surface level of the substrate 100 after the first polishing process and the second polishing process. In a case in which a surface level of the substrate 100 is not uniform, a third polishing process may be further performed in the third polishing apparatus C of FIGS. 5A and 5B. The third polishing process may polish only a portion of a surface of the substrate 100. Furthermore, the measuring of the surface level of the substrate in operation S1 may be performed multiple times, including prior to the polishing process, after the first polishing process but before the second polishing process, after the second polishing process, and combinations thereof.

The polishing process of the substrate processing method S100 according to one or more embodiments may include the first polishing process and the second polishing process. A temperature (for example, temperature of the first chuck CHC1) for the first polishing process may be lower than a temperature (for example, temperature of the second chuck CHC2) for the second polishing process. According to Equation (1) described above, polishing rate of the first polishing apparatus A may be lower than polishing rate of the second polishing apparatus B. In addition, the first plasma nozzle PN1 of the first polishing apparatus A may have a smaller diameter than the second plasma nozzle PN2 of the second polishing apparatus B. Accordingly, the first polishing process may finely polish the substrate 100, and the second polishing process may rapidly polish the substrate 100. Thus, the substrate may be efficiently polished in the substrate processing method(S).

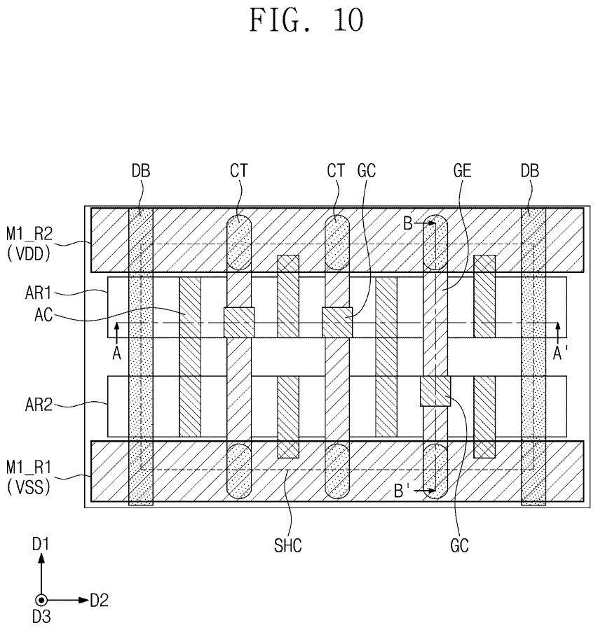

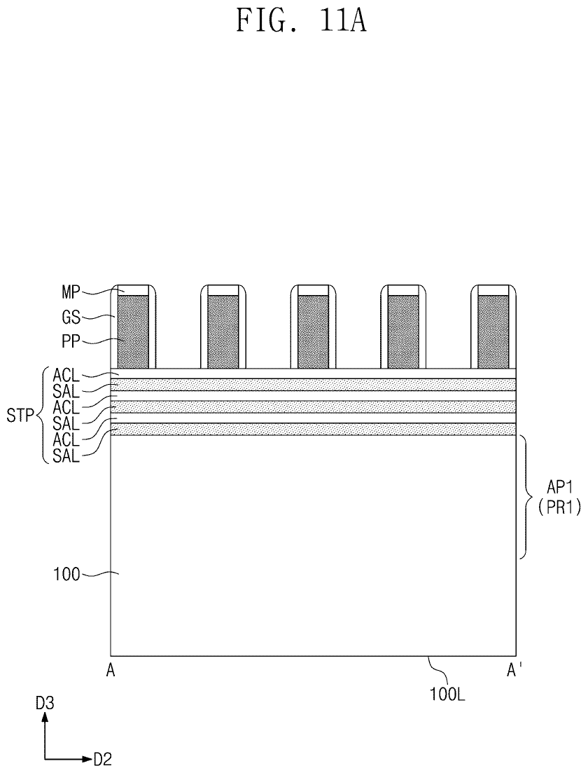

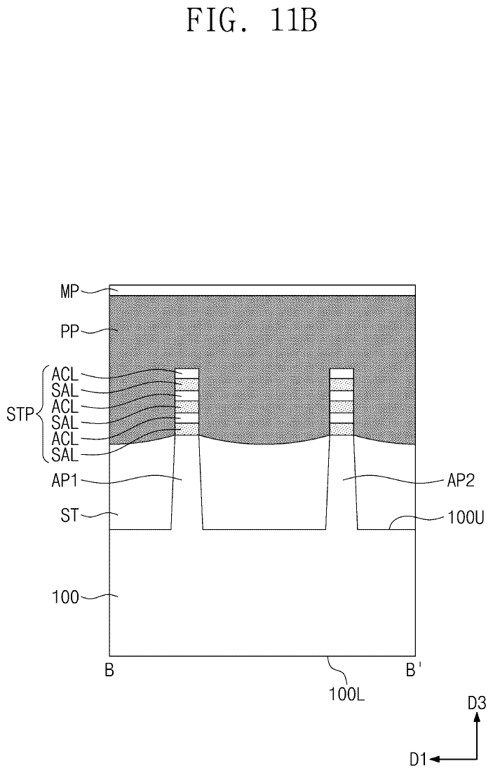

FIGS. 10 to 16B are diagrams illustrating a semiconductor device manufacturing method according to one or more embodiments. FIG. 10 is a plan view of a semiconductor device according to one or more embodiments, FIGS. 11A, 12A, 13A, 14A, 15A, and 16A are cross-sections taken along line A-A′ of FIG. 10, and FIGS. 11B, 12B, 13B, 14B, 15B, and 16B are cross-sections taken along line B-B′ of FIG. 10.

Referring to FIGS. 10, 11A, and 11B, a substrate 100 including first and second active regions AR1 and AR2 may be provided. In addition, the substrate 100 may have a first surface 100U and a second surface 100L opposite to the first surface 100U. Alternately stacked active layers ACL and sacrificial layers SAL may be formed on the first surface 100U of the substrate 100. For example, the sacrificial layers SAL may include a material having etch selectivity with respect to the active layers ACL.

A first active pattern AP1 and a second active pattern AP2 may be formed on the first surface 100U of the substrate 100 through a patterning process using mask patterns. The first active pattern AP1 may be formed on the first active region AR1, and the second active pattern AP2 may be formed on the second active region AR2. In a plan view, the first and second active patterns AP1 and AP2 may have line shapes extending in parallel to each other in a second direction D2.

A stack pattern STP may be formed on each of the first and second active patterns AP1 and AP2. The stack pattern STP may include the alternately stacked active layers ACL and sacrificial layers SAL. The stack pattern STP may be formed together through a patterning process of forming the first and second active patterns AP1 and AP2.

Thereafter, a device isolation layer ST may be formed between the first and second active patterns AP1 and AP2, and sacrificial patterns PP and hard mask patterns MP may be formed on the stack pattern STP and the device isolation layer ST. Each of the sacrificial patterns PP may be formed in a line shape or a bar shape extending in a first direction D1. A pair of gate spacers GS may be formed on both sidewalls of each of the sacrificial patterns PP.

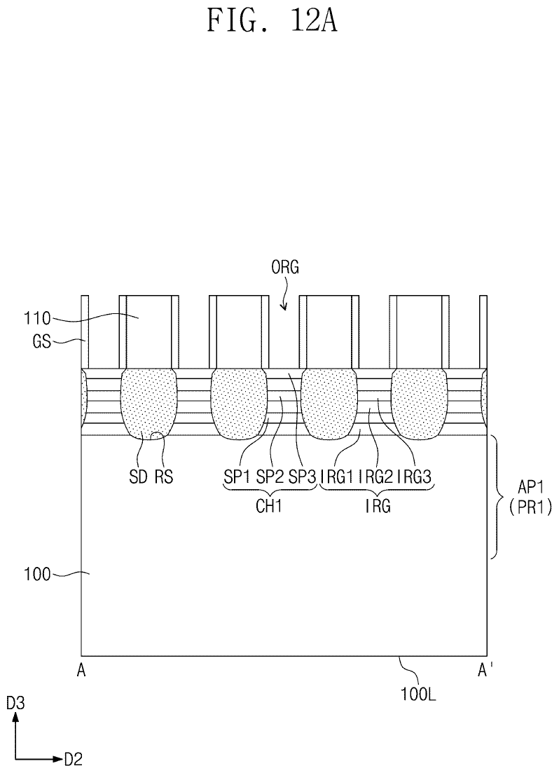

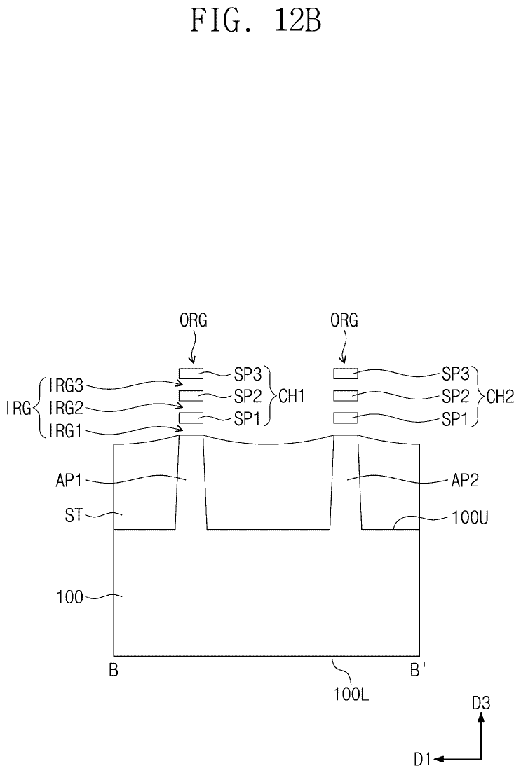

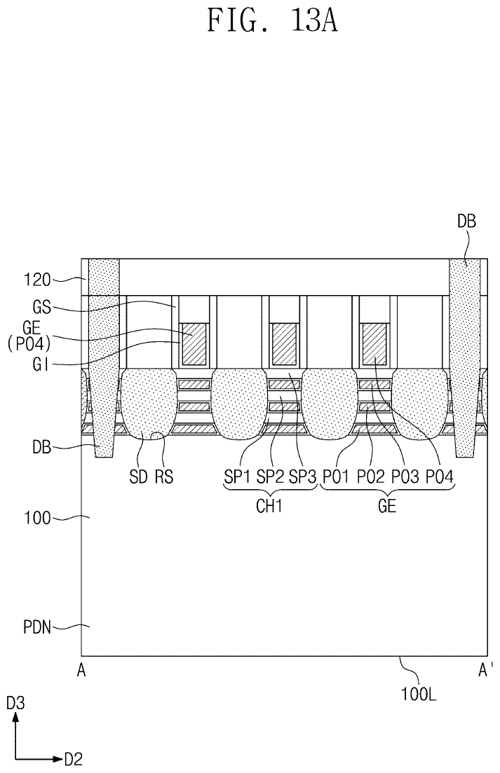

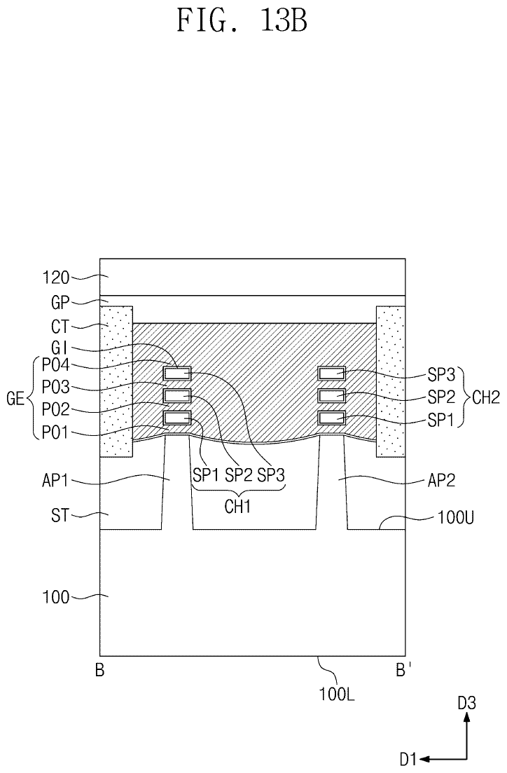

Referring to FIGS. 10, 12A, and 12B, recesses RS may be formed in the stack pattern STP on the first and second active patterns AP1 and AP2. The recesses RS may be formed through an etching process in which the hard mask patterns MP and the gate spacers GS are used as an etch mask.

Source/drain patterns SD may be respectively formed in the recesses RS. The source/drain patterns may be formed through a selective epitaxial growth (SEG) process in which inner sidewalls of the recesses RS are used as a seed layer. For example, the SEG process may include a chemical vapor deposition (CVD) process or a molecular beam epitaxy (MBE) process.

During forming the source/drain patterns SD, an impurity may be in-situ injected into the source/drain patterns SD. Alternatively, an impurity may be injected into the source/drain patterns SD after forming the source/drain patterns SD.

A first interlayer insulating layer 110 may be formed on the source/drain patterns SD, the hard mask patterns MP, and the gate spacers GS. A planarization process may be performed on the first interlayer insulating layer 110 until upper surfaces of the sacrificial patterns PP are exposed. The sacrificial patterns PP may be exposed by removing all the hard mask patterns MP through the planarization process.

The exposed sacrificial patterns PP may be selectively removed. An outer region ORG exposing first and second channel patterns CH1 and CH2 may be formed by removing the sacrificial patterns PP. Inner regions IRG may be formed by selectively removing the sacrificial layers SAL through the outer region ORG.

The first and second channel patterns CH1 and CH2 including first to third semiconductor patterns SP1, SP2, and SP3 stacked on each of the first and second active patterns AP1 and AP2 may be formed by selectively removing the sacrificial layers SAL. First to third inner regions IRG1, IRG2, and IRG3 may be respectively formed through regions in which the sacrificial layers SAL are removed.

Referring to FIGS. 10, 13A, and 13B, a gate insulating layer GI may be formed to a uniform thickness on the first to third semiconductor patterns SP1, SP2, and SP3. A gate electrode GE may be formed on the gate insulating layer GI. The gate electrode GE may include first to third inner gate electrodes PO1, PO2, and PO3 respectively formed in the first to third inner regions IRG1, IRG2, and IRG3 and an outer gate electrode PO4 formed in the outer region ORG. Accordingly, the gate electrode GE may surround the first to third semiconductor patterns SP1, SP2, and SP3.

After the gate electrode GE is formed, gate cutting patterns CT penetrating the gate electrode GE and a gate capping pattern GP covering the gate electrode GE and the gate cutting patterns CT may be formed.

A second interlayer insulating layer 120 may be formed on the first interlayer insulating layer 110. An isolation structure DB from the second interlayer insulating layer 120 toward the substrate 100 may be formed. The isolation structure DB may extend from the second interlayer insulating layer 120 to the first and second active patterns AP1 and AP2 through the gate electrode GE.

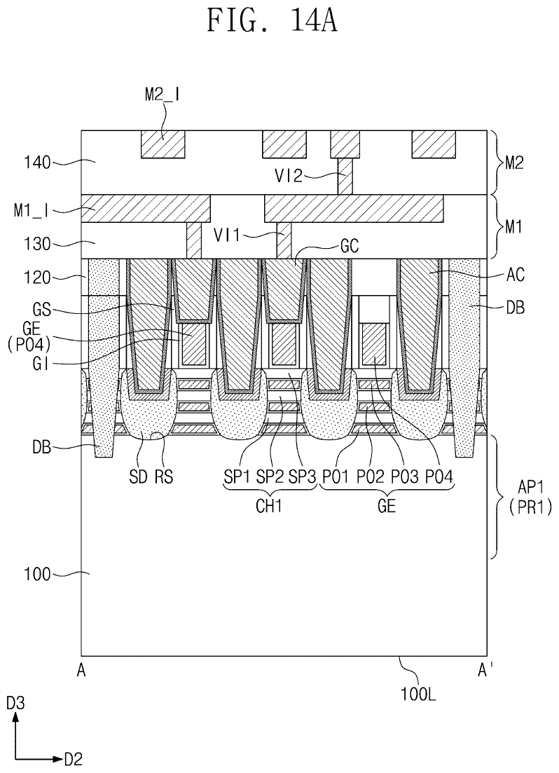

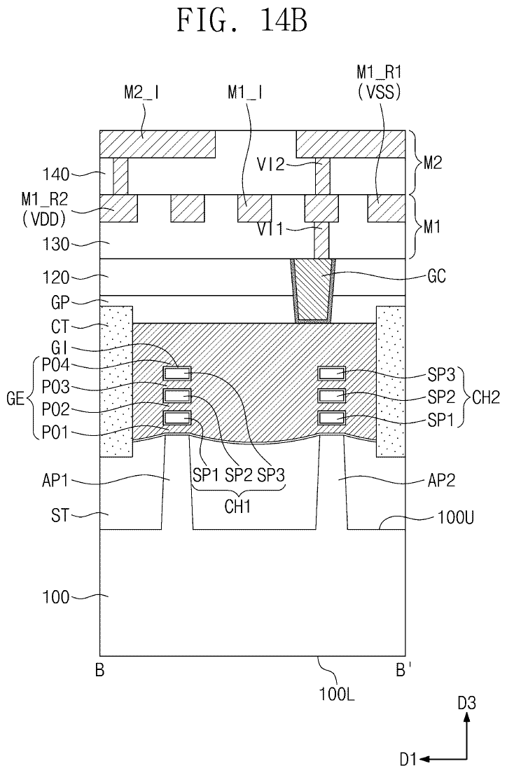

Referring to FIGS. 10, 14A, and 14B, active contacts AC penetrating the second interlayer insulating layer 120 and the first interlayer insulating layer 110 and electrically connected to the source/drain patterns SD may be formed. Gate contacts GC penetrating the second interlayer insulating layer 120 and the gate capping pattern GP and electrically connected to the gate electrode GE may be formed. A third interlayer insulating layer 130 may be formed on the active contacts AC and the gate contacts GC.

A first metal layer M1 including first lines M1_I, first vias VI1, a first power line M1_R1, and a second power line M1_R2 may be formed in the third interlayer insulating layer 130. A fourth interlayer insulating layer 140 may be formed on the third interlayer insulating layer 130. A second metal layer M2 including second lines M2_I and second vias VI2 may be formed in the fourth interlayer insulating layer 140.

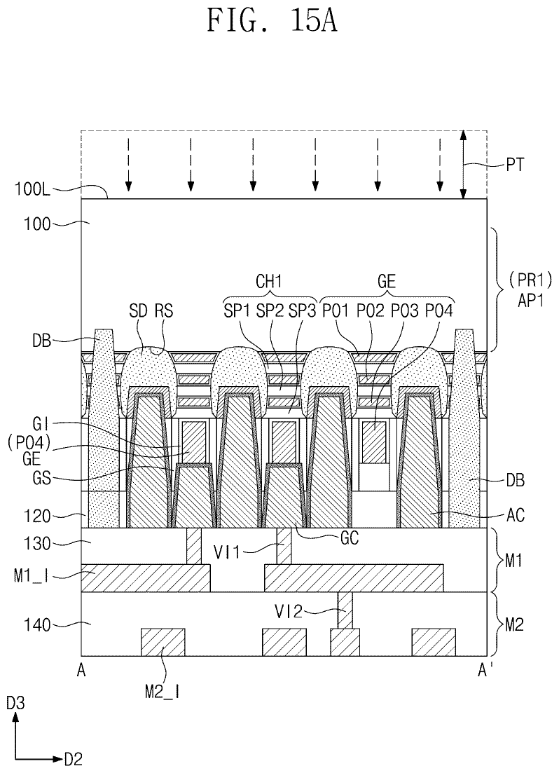

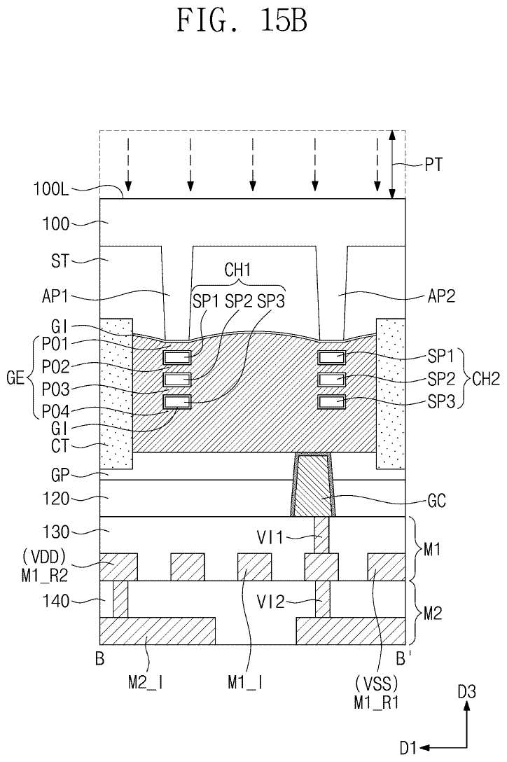

Referring to FIGS. 10, 15A, and 15B, the substrate 100 may be turned upside down. Accordingly, the second surface 100L of the substrate 100 may be higher than the first surface 100U. In addition, the second surface 100L of the substrate 100 may be exposed. A polishing process may be performed on the exposed second surface 100L of the substrate 100. The polishing process may include a first polishing process and a second polishing process using plasma. For example, the polishing process may include the substrate processing method S100 described with reference to FIGS. 6 to 9.

More specifically, after a surface level of the second surface 100L of the substrate 100 is measured, the first polishing process may be performed in the first polishing apparatus A, and the second polishing process may be performed in the second polishing apparatus B described with reference to FIGS. 2A to 4. That is, the first polishing process may polish the second surface 100L of the substrate 100 by using a plasma nozzle having a small diameter at a relatively low temperature. The second polishing process may polish the second surface 100L of the substrate 100 by using a plasma nozzle having a large diameter at a relatively high temperature. Accordingly, a thickness of the substrate 100 may be reduced by a polishing thickness PT. The polishing thickness PT may be a sum of the first polishing thickness PT1 and the second polishing thickness PT2 described with reference to FIGS. 8 and 9. As a result, the second surface 100L of the substrate 100 may have a uniform surface level.

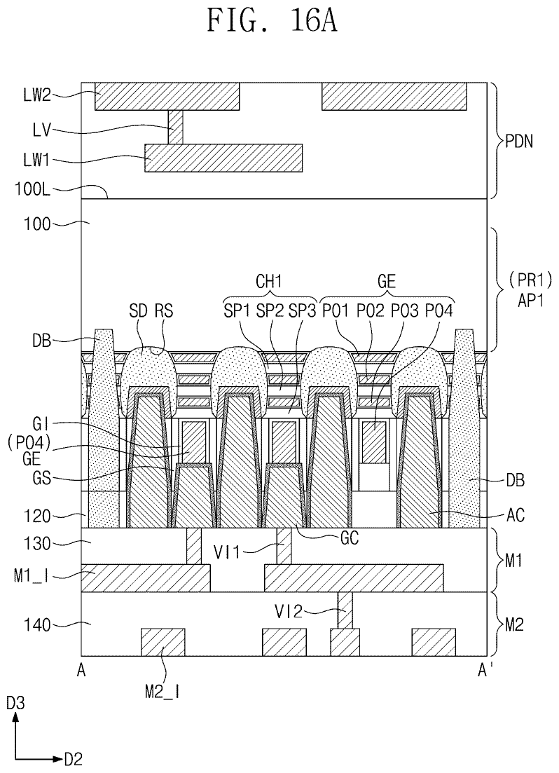

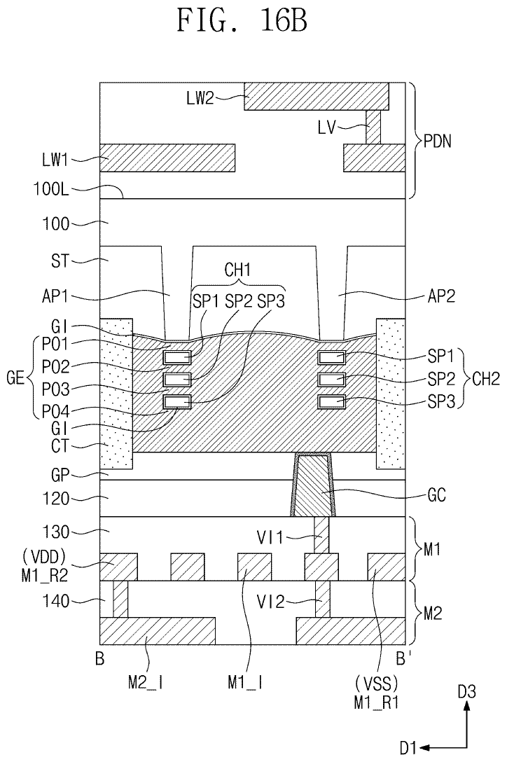

Referring to FIGS. 10, 16A, and 16B, a power delivery network layer PDN may be formed on the second surface 100L of the substrate 100. Forming the power delivery network layer PDN may include forming first lower lines LW1, forming lower vias LV on the first lower lines LW1, and forming second lower lines LW2 connected to the lower vias LV on the first lower lines LW1. The power delivery network layer PDN may be formed so as to apply a source voltage or a drain voltage to the first and second power lines M1_R1 and M1_R2.

A substrate processing system according to one or more embodiments may include a first polishing apparatus which shallowly polishes a substrate at a small width by using a plasma nozzle having a small diameter and a chuck having a low temperature and a second polishing apparatus which deeply polishes the substrate at a large width by using a plasma nozzle having a large diameter and a chuck having a high temperature. Thus, the substrate processing system may efficiently polish the substrate by using polishing apparatuses having various polishing rate.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A substrate processing system comprising:
a measuring apparatus configured to measure a surface level of a substrate;
a transfer module connected to the measuring apparatus;
a first polishing apparatus connected to the transfer module and comprising a first chuck and a first plasma nozzle facing the first chuck; and
a second polishing apparatus connected to the transfer module and comprising a second chuck and a second plasma nozzle facing the second chuck,
wherein a diameter of the second plasma nozzle is larger than a diameter of the first plasma nozzle.

2. The substrate processing system of claim 1, wherein the first plasma nozzle comprises a first inner electrode and a first outer electrode spaced apart from the first inner electrode,
wherein the first inner electrode and the first outer electrode are configured to form plasma,
wherein the second plasma nozzle comprises a second inner electrode and a second outer electrode spaced apart from the second inner electrode, and
wherein the second inner electrode and the second outer electrode are configured to form plasma.

3. The substrate processing system of claim 1, wherein the diameter of the first plasma nozzle is in a range of 8 mm to 10 mm, and
wherein the diameter of the second plasma nozzle is in a range of 20 mm to 30 mm.

4. The substrate processing system of claim 1, further comprising:
a first chiller connected to the first chuck and configured to control a temperature of the first chuck; and
a second chiller connected to the second chuck and configured to control a temperature of the second chuck.

5. The substrate processing system of claim 4, wherein the temperature of the first chuck is lower than the temperature of the second chuck.

6. The substrate processing system of claim 4, wherein the temperature of the first chuck is in a range of 80° C. to 120° C., and
wherein the temperature of the second chuck is in a range of 250° C. to 300° C.

7. The substrate processing system of claim 4, further comprising:
a third polishing apparatus connected to the transfer module and comprising a third chuck and a third plasma nozzle on the third chuck; and
a third chiller connected to the third chuck and configured to control a temperature of the third chuck,
wherein the temperature of the third chuck is lower than the temperature of the first chuck and the temperature of the second chuck.

8. A substrate processing method comprising:
measuring a surface level of a substrate; and
performing a polishing process on the substrate based on the measured surface level of the substrate,
wherein the performing of the polishing process comprises:
performing a first polishing process in a first polishing apparatus, and
performing a second polishing process in a second polishing apparatus, and
wherein a temperature of the first polishing process is lower than a temperature of the second polishing process.

9. The substrate processing method of claim 8, wherein the measuring of the surface level of the substrate is performed prior to the performing of the polishing process.

10. The substrate processing method of claim 8, wherein the performing of the first polishing process comprises polishing the substrate to a first polishing thickness of the substrate, and
wherein the performing of the second polishing process comprises polishing the substrate to a second polishing thickness that is smaller than the first polishing thickness.

11. The substrate processing method of claim 8, wherein a surface of the substrate has a highest point and a lowest point, and
wherein the performing of the first polishing process comprises reducing a difference between the lowest point and the highest point.

12. The substrate processing method of claim 11, wherein, after the performing of the first polishing process, a difference between the lowest point and the highest point is equal to or smaller than 10 nm.

13. The substrate processing method of claim 8, wherein the performing of the first polishing process is performed after the performing of the second polishing process.

14. The substrate processing method of claim 8, wherein the measuring of the surface level of the substrate is performed between the performing of the first polishing process and the performing of the second polishing process.

15. The substrate processing method of claim 8, wherein the measuring of the surface level of the substrate is performed after the performing of the polishing process.

16. The substrate processing method of claim 8, wherein the first polishing apparatus comprises a first chuck supporting the substrate and a first plasma nozzle facing the first chuck,
wherein the second polishing apparatus comprises a second chuck supporting the substrate and a second plasma nozzle facing the second chuck, and
wherein a diameter of the first plasma nozzle is smaller than a diameter of the second plasma nozzle.

17. The substrate processing method of claim 16, wherein the temperature of the first chuck is lower than the temperature of the second chuck.

18. A semiconductor device manufacturing method comprising:
forming an active pattern, a source/drain pattern, a channel pattern, and a gate electrode on a first surface of a substrate;
forming a metal layer comprising lines on the gate electrode;
performing a polishing process on a second surface of the substrate that is opposite to the first surface; and
forming a power delivery network layer on the second surface,
wherein the polishing process comprises:
a first polishing process performed at a first temperature, and
a second polishing process performed at a second temperature that is different from the first temperature.

19. The semiconductor device manufacturing method of claim 18, wherein the polishing process comprises partially polishing the second surface using a plasma nozzle.

20. The semiconductor device manufacturing method of claim 18, wherein the channel pattern comprises a plurality of semiconductor patterns spaced apart from each other, and
wherein the gate electrode surrounds the plurality of semiconductor patterns.
